(19) United States
(12) Patent Application Publication
(10) Pub. No.: US 2023/0317688 A1
(43) Pub. Date: Oct. 5, 2023

(54) LIGHT-EMITTING DEVICE AND MANUFACTURING METHOD OF THE SAME

(71) Applicant: NICHIA CORPORATION, Anan-shi (JP)

(72) Inventor: Hiroaki KAGEYAMA, Tokushima-shi (JP)

(21) Appl. No.: 18/191,192

(22) Filed: Mar. 28, 2023

(30) Foreign Application Priority Data
Mar. 30, 2022 (JP) 2022-057277

(51) Int. Cl. H01L 25/075; H01L 33/48

(52) U.S. Cl. CPC H01L 25/0753; H01L 33/486

(57) ABSTRACT

A light-emitting device includes a substrate including a base body and a metal layer disposed on an upper surface of the base body, and a plurality of light-emitting elements disposed on the metal layer. The metal layer includes, between adjacent ones of the light-emitting elements, a protrusion having a top located at a position higher than upper surfaces of the adjacent ones of the light-emitting elements. A manufacturing method of a light-emitting device includes: preparing a substrate that includes a base body and a metal layer disposed on an upper surface of the base body, the metal layer including a plurality of protrusions; and placing a light-emitting element on the metal layer between adjacent ones of the protrusions.

### CROSS-REFERENCE TO RELATED APPLICATION

This application claims priority to Japanese Patent Application No. 2022-057277, filed on Mar. 30, 2022, the disclosure of which is hereby incorporated herein by reference in its entirety.

### BACKGROUND

An embodiment of the present disclosure relates to a light-emitting device including a plurality of light-emitting elements and a manufacturing method of the light-emitting device.

In recent years, semiconductor light-emitting elements have been used as light sources of on-vehicle headlights and the like. As a light-emitting device used in such applications, a light-emitting device is proposed which includes a plurality of light-emitting elements to obtain desired light distribution characteristics by individually turning on each of the light-emitting elements. (See, for example, Japanese Patent Publication No. 2011-040495 and No. 2020-013948)

### SUMMARY

It is an object of the embodiment of the present disclosure to provide a light-emitting device in which a difference in brightness between a light-emitting portion and a non-light-emitting portion is clear when one of adjacent light-emitting portions is turned on and the other one of the adjacent light-emitting portions is turned off.

A light-emitting device according to an embodiment includes a substrate including a base body and a metal layer disposed on an upper surface of the base body, and a plurality of light-emitting elements disposed on the metal layer. The metal layer includes, between adjacent ones of the light-emitting elements, a protrusion having a top located at a position higher than upper surfaces of the adjacent ones of the light-emitting elements.

A manufacturing method of a light-emitting device according to an embodiment includes: preparing a substrate that includes a base body and a metal layer disposed on an upper surface of the base body, the metal layer including a plurality of protrusions; and placing a light-emitting element on the metal layer between adjacent ones of the protrusions.

According to embodiments of the present disclosure, a light-emitting device is provided in which a difference in brightness between a light-emitting portion and a non-light-emitting portion is clear.

### BRIEF DESCRIPTION OF DRAWINGS

FIG. 1A is a schematic perspective view illustrating an example of a light-emitting device according to a first embodiment.

FIG. 1B is a schematic cross-sectional view taken along a line IB-IB in FIG. 1A.

FIG. 2A is a schematic cross-sectional view illustrating an example of a light-emitting device according to a modification example of the first embodiment.

FIG. 2B is a schematic cross-sectional view illustrating an example of a light-emitting device according to a modification example of the first embodiment.

FIG. 2C is a schematic cross-sectional view illustrating an example of a light-emitting device according to a modification example of the first embodiment.

FIG. 2D is a schematic cross-sectional view illustrating an example of a light-emitting device according to a modification example of the first embodiment.

FIG. 2E is a schematic cross-sectional view illustrating an example of a light-emitting device according to a modification example of the first embodiment.

FIG. 2F is a schematic cross-sectional view illustrating an example of a light-emitting device according to a modification example of the first embodiment.

FIG. 2G is a schematic cross-sectional view illustrating an example of a light-emitting device according to a modification example of the first embodiment.

FIG. 2H is a schematic cross-sectional view illustrating an example of a light-emitting device according to a modification example of the first embodiment.

FIG. 2I is a schematic cross-sectional view illustrating an example of a light-emitting device according to a modification example of the first embodiment.

FIG. 2J is a schematic cross-sectional view illustrating an example of a light-emitting device according to a modification example of the first embodiment.

FIG. 3A is a schematic top view illustrating an example of a light-emitting device according to the first embodiment.

FIG. 3B is a schematic top view illustrating an example of a substrate of a light-emitting device according to the first embodiment.

FIG. 4A is a schematic top view illustrating an example of a light-emitting device according to a modification example of the first embodiment.

FIG. 4B is a schematic top view illustrating an example of a substrate of a light-emitting device according to a modification example of the first embodiment.

FIG. 5A is a schematic top view illustrating an example of a light-emitting device according to a second embodiment.

FIG. 5B is a schematic top view illustrating an example of a substrate of a light-emitting device according to the second embodiment.

FIG. 6A is a schematic cross-sectional process diagram illustrating an example of a manufacturing method of a light-emitting device according to a third embodiment.

FIG. 6B is a schematic cross-sectional process diagram illustrating an example of a manufacturing method of a light-emitting device according to the third embodiment.

FIG. 6C is a schematic cross-sectional process diagram illustrating an example of a manufacturing method of a light-emitting device according to the third embodiment.

FIG. 7A is a schematic cross-sectional process diagram illustrating an example of a manufacturing method of a light-emitting device according to the third embodiment.

FIG. 7B is a schematic cross-sectional process diagram illustrating an example of a manufacturing method of a light-emitting device according to the third embodiment.

FIG. 7C is a schematic cross-sectional process diagram illustrating an example of a manufacturing method of a light-emitting device according to the third embodiment.

FIG. 7D is a schematic cross-sectional process diagram illustrating an example of a manufacturing method of a light-emitting device according to the third embodiment.

FIG. 7E is a schematic cross-sectional process diagram illustrating an example of a manufacturing method of a light-emitting device according to the third embodiment.

### DETAILED DESCRIPTION

An embodiment of the present disclosure is described below with reference to the drawings. However, the following embodiment is intended to embody the technical idea of the present invention and is not intended to limit the present invention. Note that the size, positional relationship, or the like of members illustrated in each of the drawings may be exaggerated for clarity of description. In the following description, members with the same name and the same reference numerals indicate the same members or members of the same quality, and the detailed description thereof will be omitted as appropriate. The details described in an example and an embodiment may be used in other examples, embodiments, and the like.

In the present specification, the terms “upper” and “lower” are also used as a term that refers to a side from which light emitted by a light-emitting device is extracted and as a term that refers to a side opposite thereto. For example, an “upper surface” refers to a surface located on a side where light emitted by a light-emitting device is extracted, while a “lower surface” refers to a surface located on the opposite side. A plan view in the present specification refers to a plan view when viewed from a side from which light emitted by a light-emitting device is extracted. In the present specification, the terms such as “covering” and “cover” imply not only a case of direct contact, but also a case of indirect covering (for example, covering via another member), unless otherwise noted.

Light-Emitting Device

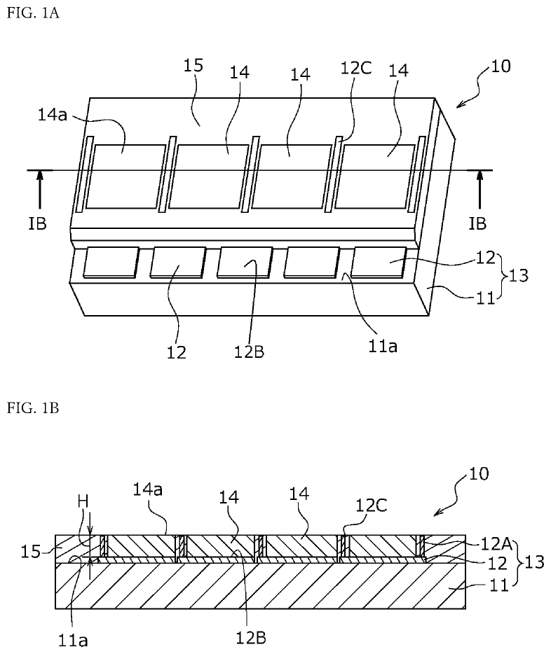

As illustrated in FIGS. 1A and 1B, a light-emitting device 10 according to the present embodiment includes a substrate 13 and a plurality of light-emitting elements 14. The substrate 13 includes a base body 11 having an upper surface, and a metal layer 12 disposed on the upper surface of the base body 11, and the plurality of light-emitting elements 14 are disposed on the metal layer 12. The metal layer 12 includes a plurality of protrusions 12A each having a top disposed at a position higher than an upper surface of the light-emitting element 14, between the light-emitting elements 14 adjacent to each other. Each of the constituent elements of the light-emitting device 10 will be described in detail below.

Substrate 13

The substrate 13 is a member configured to support the light-emitting elements 14. The substrate 13 includes the base body 11 having an upper surface 11a, and the metal layer 12 disposed on the upper surface 11a.

Base Body 11

For the base body 11, as a base body constituting a substrate for supporting electronic components such as light-emitting elements, a material known in the related technical field can be used. Examples of the known material include insulating members such as glass epoxy, resin, and ceramics, a semiconductor member such as silicon, and a conductive member such as copper. In particular, ceramics with high heat resistance and weather resistance can be preferably used. Examples of the ceramics include aluminum oxide, aluminum nitride, silicon nitride, mullite and the like. The above-mentioned ceramics may be combined with, for example, an insulating material such as a BT resin, glass epoxy, or epoxy resin. In a case in which a semiconductor member, a metal member, or the like is used as the base body, the metal layer 12 can be disposed on the upper surface 11a of the base body 11 with an insulating layer interposed therebetween. The base body 11 has the upper surface 11a and a lower surface on the opposite side from the upper surface 11a. Each of the upper surface and the lower surface are preferably substantially flat, and more preferably substantially parallel to each other. The base body 11 has a plate-like shape, for example.

Metal Layer 12

The metal layer 12 is disposed on the upper surface 11a of the base body 11. The metal layer 12 includes the protrusions 12A and a flat portion 12B surrounding each of the protrusions 12A in a plan view. Each of the protrusions 12A has the same configuration, and thus, the features of the single protrusion 12A are described herein unless otherwise noted.

Examples of the metal layer 12 include a single layer or a layered layer of a metal such as gold, aluminum, silver, copper, tungsten, titanium, platinum, nickel, palladium, iron, tin or the like, or an alloy containing at least one of them. The metal layer 12 may be partially made of a different material. For example, in the metal layer 12, the protrusion 12A and the flat portion 12B may be made of the same metal material, or may be made of different metal materials. Among them, the protrusion 12A is preferably made of a highly reflective metal such as gold, silver, aluminum or the like, or preferably includes a highly reflective metal film made of gold, silver, aluminum or the like at least on the outermost surface. As described above, the protrusion 12A is made of a metal material that can block (preferably reflect) light emitted from the light-emitting element 14, thereby suppressing the propagation of light between adjacent light-emitting elements. Specifically, when one of the two light-emitting elements adjacent to each other is turned on and the other one is turned off, it is possible to suppress a situation in which light emitted from the turned-on light-emitting element is absorbed and/or reflected by the turned-off light-emitting element. This makes it possible to suppress the occurrence of pseudo-lighting in which the turned-off light-emitting element seems to be slightly emitting light.

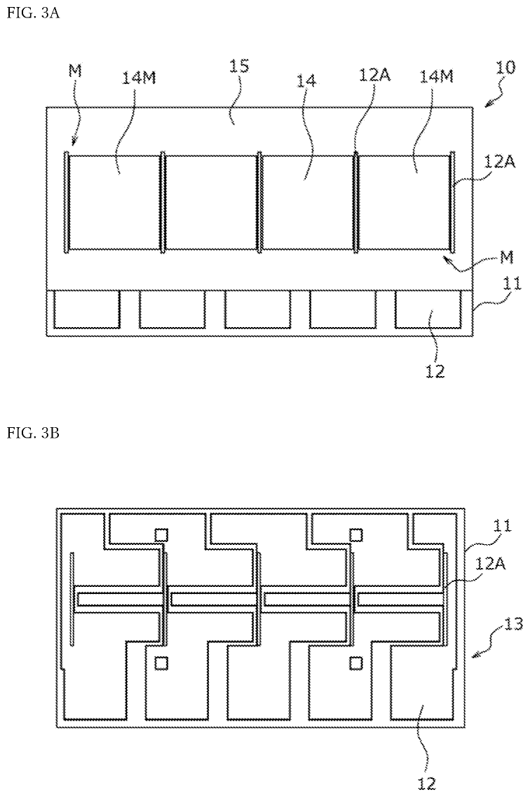

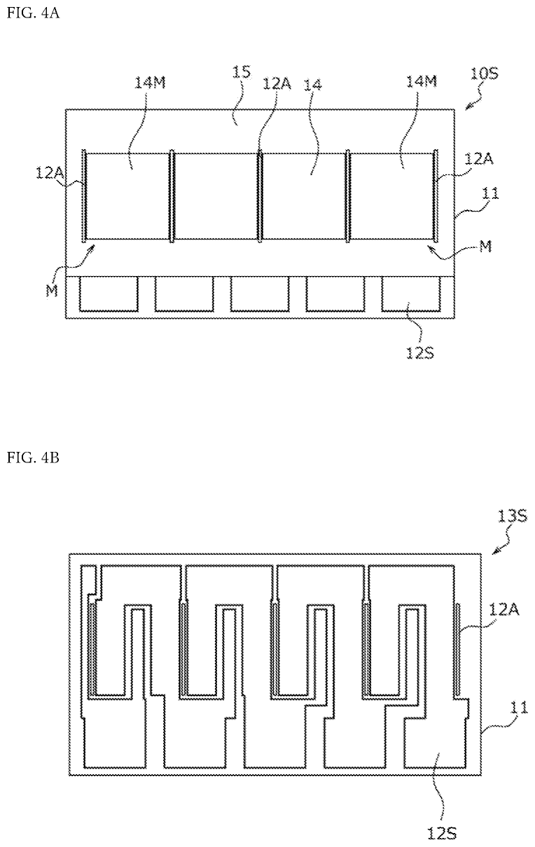

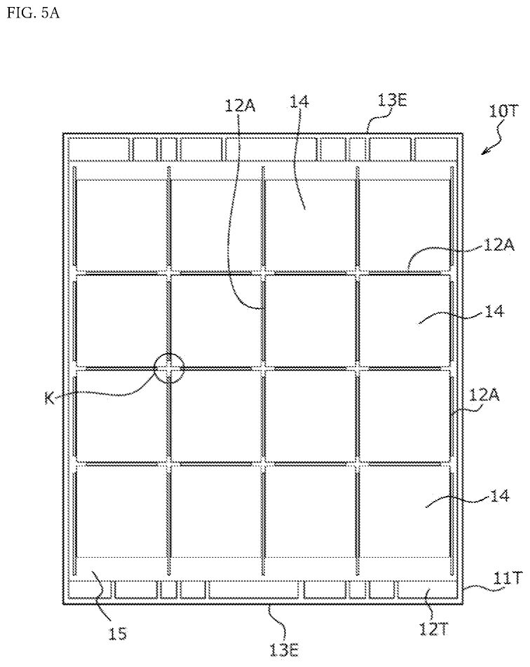

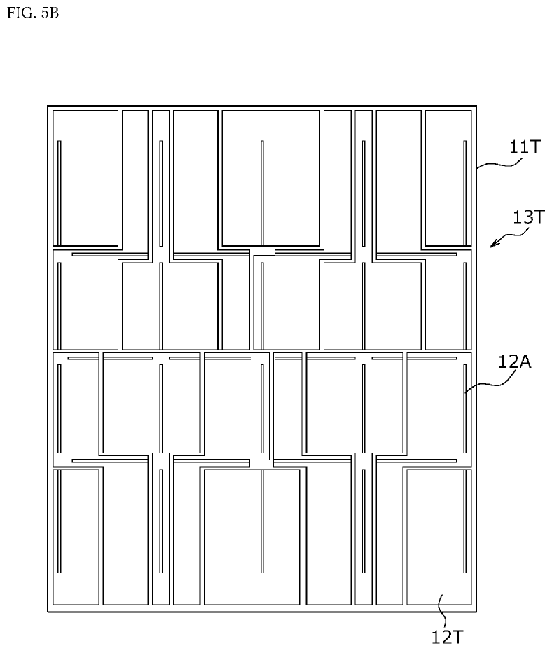

The metal layer 12 can act as wiring lines of the substrate 13 to supply electric power to electronic components such as the light-emitting elements 14 and a protective element which are disposed on the substrate 13. For this reason, the metal layer 12 includes a circuit pattern that can individually drive a plurality of light-emitting elements 14. The above-mentioned circuit pattern that can individually control lighting is known in the related technical field, and a commonly-used circuit pattern can be used. For example, the metal layer 12 illustrated in FIG. 3B and a metal layer 12S of a substrate 13S illustrated in FIG. 4B each includes a circuit pattern in which four light-emitting elements are arranged in one direction in the plan view and can be individually driven, and a metal layer 12T on a base body 11T of a substrate 13T illustrated in FIG. 5B includes a circuit pattern in which light-emitting elements are arranged in a four-by-four matrix in the plan view and can be individually driven.

The entire upper surface, other than the protrusion 12A, of the metal layer 12 is preferably the flat portion 12B. The flat portion 12B refers to a flat region of the upper surface of the metal layer 12. Specifically, it refers to that the upper surface is not intentionally processed to provide unevenness, and for example, an upper surface of the flat portion is allowed to have a surface roughness of about several nanometers or less. The thickness of the flat portion 12B in the metal layer 12 (that is, the shortest distance from the upper surface of the base body 11 to the upper surface of the flat portion 12B) may be a thickness that is typically applied to wiring lines of the substrate in the related technical field, and the thickness may be in a range from 1 μm to 10 μm, for example.

The protrusion 12A is disposed between the adjacent light-emitting elements, and has a function to suppress the light propagation between the light-emitting elements. Thus, as illustrated in FIG. 1B, the uppermost portion (hereinafter, may be referred to as a “top 12C”) of the protrusion 12A is preferably positioned above an upper surface 14a of the light-emitting element 14 placed at the flat portion 12B (that is, disposed at a position higher than the upper surface of the base body 11). For example, a height H of the protrusion 12A from the upper surface of the flat portion 12B in FIG. 1B is 10 μm or more, and is preferably 40 μm or more. Further, the height H of the protrusion 12A from the upper surface of the flat portion 12B in FIG. 1B is 350 μm or less, and is preferably 75 μm or less.

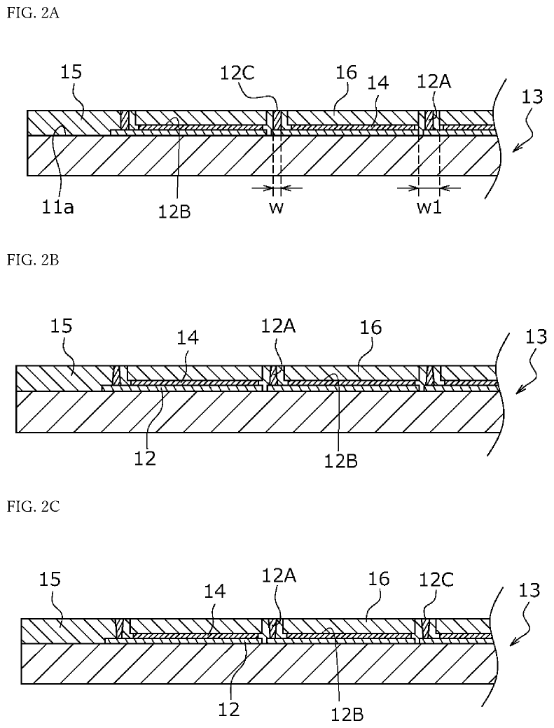

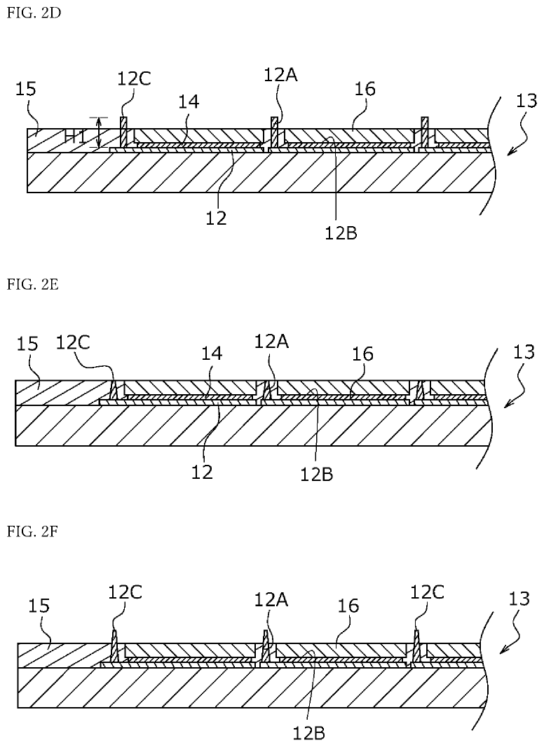

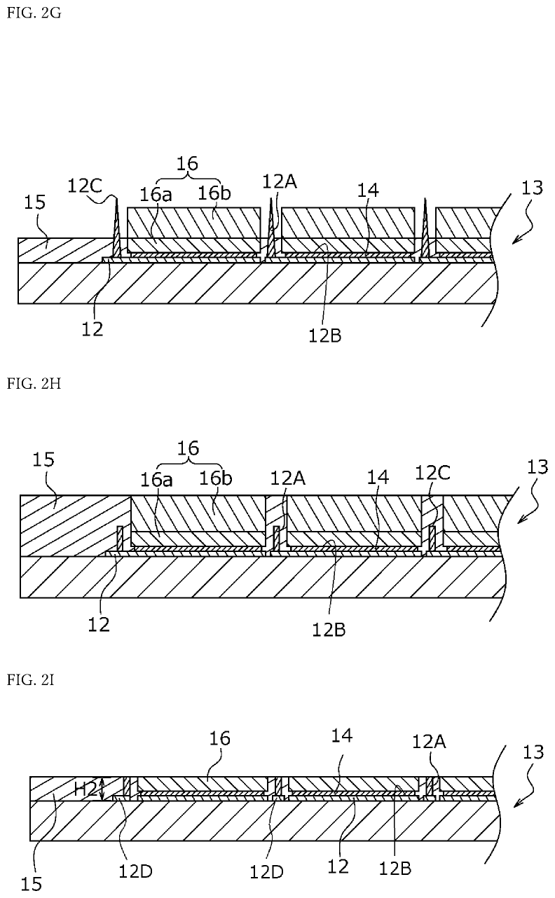

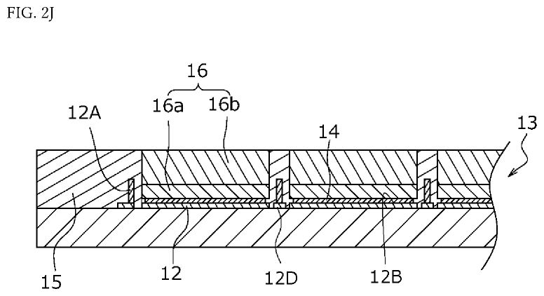

As illustrated in FIGS. 2A to 2J, the light-emitting device 10 may include an optical member such as a light-transmissive member 16 on the upper surface of the light-emitting element 14. In the light-emitting device 10, when the light-transmissive member 16 is disposed on the light-emitting element 14, the top 12C of the protrusion 12A may be disposed at a position lower than the upper surface of the light-transmissive member 16 (for example, FIGS. 2H and 2J), may be disposed at a position equivalent to the position of the upper surface of the light-transmissive member 16 (for example, FIGS. 2A to 2C, 2E, and 2I), or may be disposed at a position higher than the upper surface of the light-transmissive member 16 (for example, FIGS. 2D, 2F, and 2G). In particular, the top 12C is preferably disposed at the position equivalent to the position of the upper surface of the light-transmissive member 16, or at the position higher than the upper surface of the light-transmissive member 16. This makes it possible to suppress a situation in which light leaks and propagates in a lateral direction through the light-transmissive member 16. In this case, a height H1 of the protrusion 12A from the upper surface of the metal layer 12 in FIG. 2D is, for example, 20 μm or more, and is preferably 50 μm or more. Further, the height H1 of the protrusion 12A from the upper surface of the metal layer 12 in FIG. 2D is, for example, 400 μm or more, and is preferably 100 μm or less. As illustrated in FIGS. 2A to 2H, the protrusion 12A may be disposed on a portion of the metal layer 12 (a first portion of the metal layer) on which the light-emitting element is placed. As illustrated in FIGS. 2I and 2J, the protrusion 12A may be disposed on the base body 11 while being separated from the first portion of the metal layer 12 on which the light-emitting element is placed. In this case, the substrate 13 may include a second metal layer 12D (a second portion of the metal layer) having a thickness equivalent to that of the flat portion 12B, between the protrusion 12A and the base body 11. When the metal layer 12 includes the second metal layer 12D, the height of the protrusion 12A (that is, H2 in FIG. 2I) is a thickness obtained by adding a thickness corresponding to the thickness of the second metal layer 12D to the height H or H1 described above.

The width of the protrusion 12A (for example, W in FIG. 2A) is smaller than a distance (for example, W1 in FIG. 2A) by which the adjacent light-emitting elements 14 are separated from each other. Specifically, the width W of the protrusion 12A is preferably 50 μm or less. In this case, as illustrated in FIG. 2A, the width W refers to the length of the metal layer 12 in a direction in which lateral surfaces of the adjacent light-emitting elements face each other. The width W of the protrusion 12A may be constant in a height direction, may decrease upward as illustrated in FIGS. 2B and 2E to 2G, or may increase upward as illustrated in FIG. 2C. The width of the protrusion 12A may partially vary or may be constant in the plan view. The plurality of protrusions 12A may be arranged along a curved line or a straight line in the plan view. The height of the protrusion 12A may partially vary or may be constant. In particular, as for the protrusions 12A, the protrusions 12A having a constant width are preferably arranged in a straight-line between the light-emitting elements in the plan view. Furthermore, the height of the protrusion 12A is preferably constant between the light-emitting elements. This makes it possible to suppress light leakage between adjacent light-emitting elements and to achieve a light-emitting device in which a difference in brightness between a light-emitting portion and a non-light-emitting portion is distinct and clear.

The protrusion 12A is disposed on the base body 11 between regions where the light-emitting elements 14 are disposed in the plan view. In this case, the protrusions 12A can be disposed in all of the spaces or some of the spaces between adjacent light-emitting elements. For example, when a plurality of light-emitting elements are aligned in a row, the protrusions 12A may be disposed between all of adjacent light-emitting elements, or may be disposed between some of the adjacent light-emitting elements. When the plurality of light-emitting elements are aligned in two rows, one protrusion 12A may be disposed across between all of the light-emitting elements adjacent in a column direction, or the protrusion 12A may be disposed between some of the light-emitting elements adjacent in the column direction. When a plurality of light-emitting elements are disposed in a matrix, the protrusion 12A may be disposed between any light-emitting elements adjacent in the row direction and/or in the column direction, or may be disposed between all of the adjacent light-emitting elements. The arrangement of the protrusions 12A can be changed as appropriate in accordance with the arrangement, purpose, and application of the light-emitting elements. In particular, the protrusions 12A are preferably disposed between all adjacent ones of the light-emitting elements, and more preferably the protrusions 12A are also disposed outside the outermost light-emitting elements disposed in rows or columns as illustrated in FIG. 1A and the like. The protrusion 12A may be disposed at part of the mutually facing sides of the adjacent light-emitting elements in the plan view, but is preferably disposed with a length equal to or longer than the mutually facing sides of the adjacent light-emitting elements. For example, as illustrated in FIGS. 3A and 4A, when the plurality of light-emitting elements 14 in the light emitting device 10 (FIG. 3A) or the light emitting device 10S (FIG. 4A) are arranged in a row in one direction, the protrusion 12A may extend in a direction orthogonal to the one direction in the plan view from between the adjacent light-emitting elements 14, and may be disposed with a length equal to or greater than the length of the mutually facing sides of the adjacent light-emitting elements 14. Similarly, when a plurality of light-emitting elements 14 are arranged in a row in one direction, a plurality of the protrusions 12A may be disposed in a row in a direction orthogonal to the one direction. As illustrated in FIG. 5A, when the plurality of light-emitting elements 14 in the light emitting device 10T are arranged in a matrix, the protrusions 12A are preferably disposed between all of the adjacent light-emitting elements 14. Any of the configurations illustrated in FIGS. 2A-2J can be applied to the light emitting device 10T in which the light emitting elements 14 are arranged in a matrix. In this case, between all of the adjacent light-emitting elements 14, the protrusions 12A are preferably disposed along the mutually facing sides of the adjacent light-emitting elements 14 with a length equal to or greater than the length of the mutually facing sides. The protrusions 12A disposed between the light-emitting elements adjacent in the row direction and/or the column direction may be disposed with the same length in the plan view, or some of the protrusions 12A may be disposed with different lengths. For example, as illustrated in FIG. 5A, the protrusion 12A may be extended from between the light-emitting elements adjacent in one direction toward a direction orthogonal to the one direction (here, toward an end portion 13E direction of the substrate 13). The above-described arrangement makes it possible to suppress a situation in which light emitted from one light-emitting element interferes with an adjacent light-emitting element. Here, the length of the extended portion is in a range from 1/30 to 1/10 of one side of the light-emitting element, or in a range from 1/30 to 1/20 thereof. The above-discussed arrangement of the protrusion 12A makes it possible to suppress the propagation of light between the light-emitting elements to clarify a difference in brightness when one of the adjacent light-emitting elements is turned on and the other is turned off. As illustrated in FIGS. 3A and 4A, the protrusion 12A may be disposed outside an outermost light-emitting element 14M (that is, on a side M to which the light-emitting element 14 is not adjacent) located outside the plurality of light-emitting elements arranged in one direction (that is, the outermost light-emitting element among the light-emitting elements arranged in the one direction). As a result, the light distribution of the light-emitting element 14M located on the outer side can be equivalent to the light distribution of the light-emitting element 14 located on the inner side.

As illustrated in FIG. 5A and FIG. 5B, when the light-emitting elements 14 are arranged in a matrix, the protrusions 12A are preferably disposed intermittently in the row direction and/or the column direction in the plan view. In other words, the protrusion 12A disposed between the light-emitting elements arranged in a two-by-two matrix or more may be disposed as a single protrusion 12A continuous in the row direction and/or the column direction, but preferably disposed as a plurality of the protrusions 12A separated from each other. For example, as illustrated in FIG. 5A, when a light-emitting device includes 4 light-emitting elements disposed in a 2-by-2 matrix, four protrusions 12A disposed between four light-emitting elements are preferably disposed so as not to be continuous at a central portion K of the four light-emitting elements in the plan view as illustrated in FIG. 5A. The protrusions 12A are preferably disposed with the same spacing between the four light-emitting elements at the central portion K in the row and column directions. As described above, when a plurality of protrusions 12A are arranged intermittently around the light-emitting element, that is, when the plurality of protrusions 12A are disposed at a predetermined interval, a covering member described below can easily flow between the light-emitting elements from one direction or a plurality of directions, and thus the covering member can be easily disposed to cover the lateral surfaces of the light-emitting elements.

Light-Emitting Element 14 The plurality of light-emitting elements 14 are disposed on the metal layer 12 of the substrate 13. A known light-emitting element such as a semiconductor laser, or a light-emitting diode can be used for the light-emitting element 14. The light-emitting element 14 is, for example, a light-emitting diode.

The composition, luminescent color or wavelength, size, number, and the like of the light-emitting element 14 may be selected as appropriate in accordance with an intended purpose. A light-emitting element to be used to emit light with wavelengths of blue to green colors includes a semiconductor layer of ZnSE, a nitride-based semiconductor (In_{X}Al_{Y}Ga_{1-X-Y}N, 0≤X, 0≤Y, X+Y≤1), GaP, or the like. A light-emitting element to be used to emit light with a wavelength of a red color includes a semiconductor layer of GaAlAs, AlInGaP, or the like.

The light-emitting element 14 includes, for example, a light-transmissive support substrate (for example, a sapphire substrate) and a semiconductor layer on the support substrate. The substrate may have unevenness at an interface with the semiconductor layer. This makes it possible to intentionally change a critical angle at which light emitted from the semiconductor layer hits the support substrate, and easily extract the light to the outside of the support substrate. The light-emitting element 14 may have a structure that does not include a support substrate. The light-emitting element that does not include the support substrate may be obtained by, after growing a semiconductor layer on a support substrate for growth, removing the substrate for growth by polishing, laser lift-off (LLO), or the like.

The light-emitting element 14 including positive and negative electrodes on the same surface side is preferably used. This makes it possible to easily mount the light-emitting element on the substrate by flip-chip mounting. In this case, a surface on the opposite side from the surface on which the positive and negative electrodes are formed acts as a primary light extraction surface. The mounting of the light-emitting element onto the substrate may be carried out using a conductive paste such as solder, or a known bonding member such as a bump. The positive and negative electrodes of the light-emitting element 14 may be directly bonded to a wiring line pattern (here, the metal layer) on the base body.

Alternatively, the surface on the opposite side from the surface where the positive and negative electrodes are formed may be a mounting surface with the substrate 13, and the surface on which the positive and negative electrodes are formed may be used as a primary light extraction surface.

The light-emitting element 14 may have the positive and negative electrodes on different surfaces. For example, in a case of a light-emitting element having an electrode structure in which the positive and negative electrodes are respectively provided on the opposite surfaces, the lower surface electrode is bonded to a metal layer, and the upper surface electrode is connected to another metal layer by a conductive wire or the like.

A plurality of light-emitting elements 14 are included in one light-emitting device. The plurality of light-emitting elements 14 are aligned on the substrate 13. For example, the light-emitting elements 14 may be arranged in a row in one direction as illustrated in FIG. 1A and the like, or may be disposed in a matrix as illustrated in FIG. 5A. The number of light-emitting elements may be appropriately set in accordance with the characteristics, size, and the like of the light-emitting device to be obtained. The plurality of light-emitting elements are preferably disposed close to each other on the substrate. From the viewpoint of brightness distribution and the like required for an automotive application, a distance between the light-emitting elements is preferably shorter than the size (for example, the length of one side) of the light-emitting element itself, and for example, the distance between the light-emitting elements is more preferably about 30% or less of the length of one side of the light-emitting element, and further preferably 20% or less. Specifically, the distance is in a range from 30 μm to 300 μm, and is preferably in a range from 30 μm to 80 μm. As described above, the light-emitting elements are disposed close to each other, so that a compact light-emitting device can be obtained. The protrusions 12A are disposed between the light-emitting elements disposed close to each other as described above, so that a difference in brightness between the light-emitting portion and the non-light-emitting portion becomes clear, and thus the light-emitting device having high resolution with a small light-emitting area can be achieved.

Covering Member 15

As illustrated in FIGS. 1A and 1B, the light-emitting device 10 preferably further includes a covering member 15 for covering the lateral surface of the light-emitting element and the lateral surface of the protrusion.

The covering member 15 preferably continuously covers the mutually facing lateral surfaces of the light-emitting elements and the lateral surfaces of the protrusions. This makes it possible to protect the light-emitting elements 14 and the protrusions from deterioration by the external environment and damage by mechanical contact.

The covering member 15 is preferably a light-blocking member, and specifically a light reflective and/or light absorbing member. In particular, a material that can reflect light emitted from the light-emitting element is preferably included. For example, the material preferably has a reflectance of 60% or more with respect to the light emitted from the light-emitting element, and more preferably has a reflectance of 70% or more, 80% or more, or 90% or more. Accordingly, the light emitted laterally from the lateral surface of the light-emitting element can be reflected inside the light-emitting element at the interface between the light emitting element and the covering member and extracted from the upper surface. As a result, the light emitted from the light-emitting element is suppressed from propagating to the adjacent light-emitting element.

The covering member 15 includes resin of a base material and particles of a light reflective material contained in the resin. Examples of the resin include resin containing one or more of a silicone resin, a modified silicone resin, an epoxy resin, a modified epoxy resin, an acrylic resin, and a fluoro-resin. Examples of the light reflective material include titanium oxide, silicon oxide, zirconium oxide, potassium titanate, aluminum oxide, aluminum nitride, boron nitride, mullite, a combination of these materials and the like. The average particle size of the light reflective material is in a range from 0.05 μm to 30 μm, for example. The covering member 15 may further include a light absorbing material such as pigment, carbon black or the like, and a wavelength conversion member such as a phosphor. In the covering member 15, the particles of the light reflective material may be unevenly distributed partially or entirely, but preferably dispersedly. The content of the light reflective material in the covering member may be adjusted as appropriate in accordance with, for example, the characteristics of the light-emitting device to be obtained. The content of the light reflective material is preferably 30 wt. % or more, for example.

A material excellent in heat dissipation may be used for the covering member 15. For example, the thermal conductivity of the covering member 15 is preferably 0.2 W/m·K or more, and more preferably 1 W/m·K or more. The thermal conductivity of the covering member 15 is set high, so that the heat dissipation of the light-emitting device 10 can be improved.

The covering member 15 may be flush or substantially flush with the upper surface 14a of the light-emitting element 14 (that is, the primary light extraction surface of the light-emitting element). The expression “substantially flush” refers to that a difference in height of about ±10% or less, preferably about ±5% or less of the thickness of the covering member is allowable. The light extraction surface refers to an upper surface of the light-transmissive member as described below in a case in which a light-transmissive member is further provided on the upper surface of the light-emitting element to cover the upper surface. Thus, when the light-transmissive member is disposed on the upper surface of the light-emitting element, the upper surface of the covering member is preferably flush with or substantially flush with the upper surface of the light-transmissive member.

Further, the protrusion is preferably exposed from the covering member on the upper surface of the light-emitting device. In this case, the height of the top of the protrusion may be the same as the height of the upper surface of the covering member, or may be lower or higher than the height of the upper surface of the covering member. In particular, the top of the protrusion preferably has a height equal to or higher than the height of the upper surface of the covering member.

The light-emitting device 10 may be provided with a protective element such as a Zener diode. In this case, the protective element is preferably embedded in the covering member. This makes it possible to suppress a reduction in light extraction due to the light emitted from the light-emitting element being absorbed or blocked by the protective element.

Light-Transmissive Member 16

The light-emitting device is preferably further provided with the light-transmissive member 16 disposed on each of the upper surfaces of the plurality of light-emitting elements. The light-transmissive member 16 is a member that can cause the light emitted from the light-emitting element to transmit therethrough and release the light to the outside. The expression “light-transmissive” herein refers to that 50% or more of the light emitted from the light-emitting element is transmitted, and it is more preferable that 60% or more, 70% or more, 75% or more, 80% or more, 85% or more, or 90% or more of the light be transmitted.

The light-transmissive member 16 may be smaller than, equal thereto, or larger than the upper surface of the light-emitting element in the plan view. The light-transmissive member 16 preferably covers the entire upper surface of the light-emitting element so that more of light emitted from the upper surface of the light-emitting element is incident thereon. Accordingly, the size of the light-transmissive member disposed on the light-emitting element is preferably larger than or equal to the size of the light-emitting element in the plan view. As a result, the light-emitting device with a higher level of brightness can be achieved.

When a plurality of light-emitting elements are individually covered with the light-transmissive members larger than the light-emitting element, a distance between the light-transmitting members is preferably shorter than the size (for example, the length of one side) of the light-transmissive member itself, and more preferably 20% or less of the length of one side of the upper surface of the light-transmissive member, for example. By disposing the light-transmissive members to be close to each other in this manner, the light-emitting device having high resolution with a small light-emitting area can be achieved.

As the light-transmissive member, a light-transmissive resin, glass, or ceramics may be used, for example. Resin containing one or more of a silicone resin, a modified silicone resin, an epoxy resin, a modified epoxy resin, an acrylic resin, and a fluoro-resin can be used for the light-transmissive resin.

The light-transmissive member 16 may contain a phosphor that can convert a wavelength of at least part of incident light. Examples of the light-transmissive member containing a phosphor include a member in which phosphor powders are contained in a sintered compact of a phosphor, a light-transmissive resin, glass, ceramics or the like, for example. A phosphor-containing layer such as a resin layer containing a phosphor may be disposed on a surface of a light-transmissive layer which is a compact of a light-transmissive resin, glass, ceramics, or the like.

For example, as illustrated in FIG. 2G, the light-transmissive member 16 includes a first light-transmissive layer 16a containing a phosphor and disposed on the upper surface of the light-emitting element 14, and a second light-transmissive layer 16b disposed on the first light-transmissive layer 16a. In this case, the top 12C of the protrusion 12A is preferably disposed at a position higher than at least the upper surface of the first light-transmissive layer 16a, and more preferably disposed at a position equal to or higher than the upper surface of the second light-transmissive layer 16b.

When the light-transmissive member 16 has a layered structure of the first light-transmissive layer 16a and the second light-transmissive layer 16b, the phosphor may be contained in both the first light-transmissive layer 16a and the second light-transmissive layer 16b, or may be contained in one of them. In particular, the phosphor is preferably contained in only the first light-transmissive layer 16a. In this case, the second light-transmissive layer 16b may be formed of any of the materials described above, but preferably contains a glass material, and more preferably is formed of glass.

Examples of the phosphor to be used include an oxynitride phosphor such as yttrium aluminum garnet phosphor (for example, Y₃(Al,Ga)₅O₁₂:Ce), lutetium aluminum garnet phosphor (for example, Lu₃(Al,Ga)₅O₁₂:Ce), terbium aluminum garnet phosphor (for example, Tb₃(Al,Ga)₅O₁₂:Ce), CCA phosphor (for example, Ca₁₀(PO₄)₆Cl₂:Eu), SAE phosphor (for example, Sr₄Al₁₄O₂₅:Eu), chlorosilicate phosphor (for example, Ca₈MgSi₄O₁₆Cl₂:Eu), β-sialon phosphor (for example, (Si,Al)₃(O,N)₄:Eu), α-sialon phosphor (for example, Ca(Si,Al)₁₂(O,N)₁₆:Eu) or the like, a nitride phosphor such as SLA phosphor (for example, SrLiAl₃N₄:Eu), CASN phosphor (for example, CaAlSiN₃:Eu), SCASN phosphor (for example, (Sr,Ca)AlSiN₃:Eu), BSESN phosphor ((Ba,Sr)₂Si₅N₈) or the like, a fluoride phosphor such as KSF phosphor (for example, K₂SiF₆:Mn), KSAF phosphor (for example, K₂Si_{0.99}Al_{0.01}F_{5.99}:Mn), MGF phosphor (for example, 3.5MgO·0.5MgF₂·GeO₂:Mn) or the like, a phosphor with a perovskite structure (for example, CsPb(F,Cl,Br,I)₃), a quantum dot phosphor (for example, CdSe, InP, AgInS₂, or AgInSe₂) or the like. The light-transmissive member may include one type of phosphor, or may include a plurality of types of phosphors. When a phosphor is contained in a light-transmissive member, the concentration of the phosphor in the light-transmissive member is preferably approximately in a range from 5% to 50%, for example.

The light-transmissive member is bonded in such a manner to cover the upper surface (light extraction surface) of the light-emitting element. The bonding between the light-transmissive member and the light-emitting element may be direct bonding such as pressure bonding, sintering, surface activated bonding or the like, or may be bonding with a known adhesive such as resin, for example.

The lateral surface of the light-transmissive member configured to cover each of the plurality of light-emitting elements is preferably covered with the covering member, and in particular more preferably the entire lateral surface of the light-transmissive member is covered with the covering member.

When the lateral surface of the light-transmissive member configured to cover each of the plurality of light-emitting elements is covered with the covering member, and the protrusion is disposed between the adjacent light-transmissive members, more preferably the covering member is also disposed between the protrusion and the light-transmissive member.

When the lateral surface of the light-transmissive member is covered with the covering member, the upper surface of the light-transmissive member is preferably flush or substantially flush with the upper surface of the covering member. This makes it possible to suppress interference between light beams emitted from the lateral surface of the light-transmissive member.

The thickness of the light-transmissive member (that is, the distance from the lower surface to the upper surface of the light-transmissive member) may be in a range from 50 μm to 300 μm, for example. In particular, the height from the lower surface to the upper surface of the light-transmissive member is preferably lower than the height from the lower surface to the upper surface of the light-emitting element.

The light-transmissive member has, for example, a substantially rectangular parallelepiped shape as a whole. In order to obtain the desired light distribution, the upper surface of the light-transmissive member may take various shapes such as a protrusion-and-recession shape, a curved surface shape, a convex lens shape and the like.

Embedded Member

In the light-emitting device, an embedded member may be disposed between the substrate and the light-emitting element. The embedded member is, for example, an underfill. By disposing the underfill between the substrate and the light-emitting element, it is possible to absorb stress due to a difference in thermal expansion coefficient between the light-emitting element and the substrate and to improve heat dissipation.

A material similar to the light-transmissive resin, the light reflective material, or the like exemplified in the description of the covering member may be used for the embedded member. Materials constituting the embedded member may be used alone, or in combination of two or more. This makes it possible to adjust the reflectance of light and/or the coefficient of linear expansion of resin.

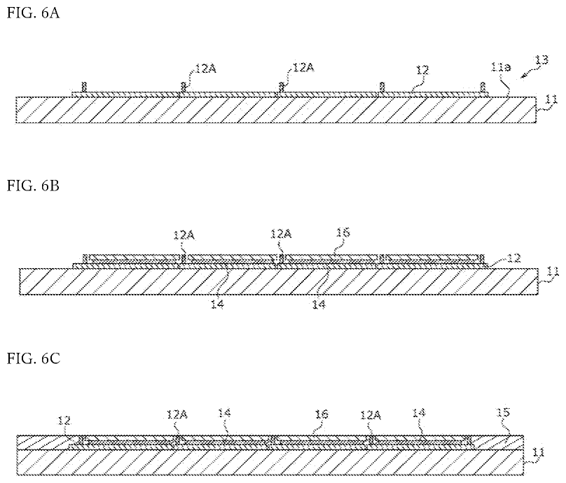

Manufacturing Method of Light-Emitting Device A manufacturing method of a light-emitting device of the present embodiment includes, preparing the substrate 13 including the base body 11 having the upper surface 11a, the metal layer 12 disposed on the upper surface 11a, and a plurality of protrusions 12A separated from each other, as illustrated in FIG. 6A, and placing the light-emitting element 14 on the metal layer 12 between the protrusions 12A adjacent to each other, as illustrated in FIG. 6B.

Preparation of Substrate

The preparation of the substrate includes, after preparing a base body disposed with a flat metal layer on the upper surface of the base body, forming protrusions on the metal layer by plating.

Preparation of Base Body

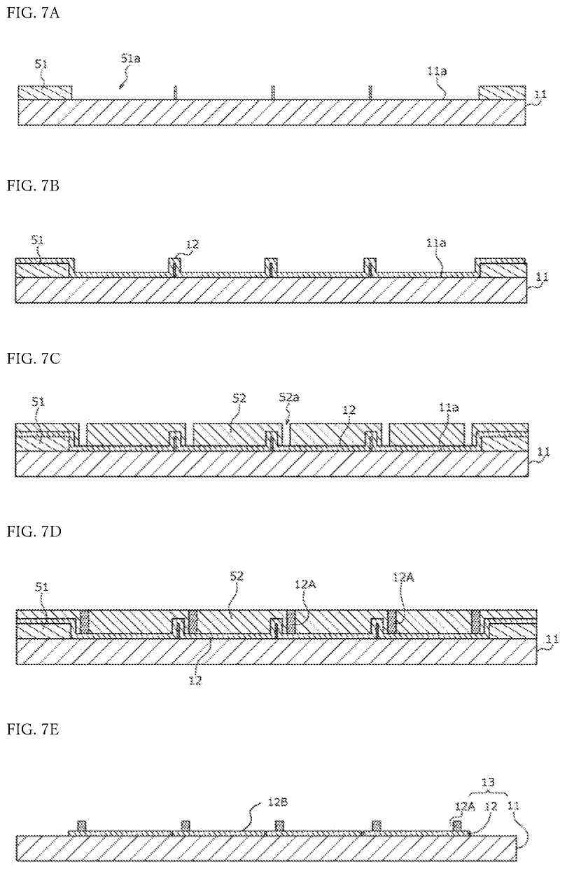

First, as illustrated in FIG. 7A, a first resist layer 51 having a desired shape is disposed on the upper surface 11a of the base body 11. The first resist layer 51 has an opening 51a in a region where the metal layer 12 (specifically, the flat portion 12B of the metal layer 12) is to be formed. Then, as illustrated in FIG. 7B, the metal layer 12 is formed on the first resist layer 51 and on the base body 11 exposed from the first resist layer 51 (that is, the opening 51a) by, for example, vapor deposition, sputtering, plating or the like.

Formation of Protrusion

Subsequently, as illustrated in FIG. 7C, a second resist layer 52 having a desired shape is disposed on the metal layer 12 formed on the first resist layer 51 and the upper surface of the base body 11 exposed from the opening 51a. The second resist layer 52 has an opening 52a in a region where the protrusion on the metal layer 12 is disposed. Then, while using the metal layer 12 formed on the first resist layer 51 and the upper surface of the base body 11 exposed from the opening 51a as a seed layer, the protrusion 12A is formed by a plating method on the metal layer 12 exposed at the bottom of the opening 52a, as illustrated in FIG. 7D. Thereafter, by removing the first resist layer 51 and the second resist layer 52, the substrate 13 including the metal layer 12 having the protrusion 12A may be obtained as illustrated in FIG. 7E.

In the above-described process, the height of each resist layer (that is, the thickness of the resist layer covering the upper surface of the substrate) is preferably equal to or higher than the height corresponding to the height of the protrusion to be obtained. When a lateral surface defining the opening of the resist layer is sloped to expand from the upper surface toward the lower surface of the resist layer, the protrusion 12A having a lateral surface that is sloped so that the width of the protrusions 12 decreases upward can be obtained as illustrated in FIGS. 2B and 2E to 2G. As a plating method, a non-electrolytic plating technique may be used, but it is preferable to use an electrolytic plating technique that can grow plating in a shorter period of time. A liquid containing at least one of copper (Cu), gold (Au), zinc (Zn), chromium (Cr), and nickel (Ni) may be used as a plating solution.

In the process described above, methods known in the related technical field may be used in addition to the above-described methods.

Disposition of Light-Emitting Element

After having prepared the substrate 13 including the metal layer 12 having the protrusion 12A as illustrated in FIG. 7E and the like, each of the light-emitting elements 14 is disposed on the metal layer 12 between the protrusions 12A as illustrated in FIG. 6B. The light-emitting element 14 is disposed on the flat metal layer 12 while being separated from the protrusion 12A.

The light-emitting element 14 can be disposed on the metal layer 12 by, for example, bonding with a bonding member. Examples of the bonding member include a conductive paste such as solder and a known bonding member such as a bump. The positive and negative electrodes of the light-emitting element 14 may be directly bonded to the metal layer 12 without interposing the bonding member therebetween.

Disposition of Light-Transmissive Member

In a case in which the light-emitting device includes the light-transmissive member 16, the light-emitting element 14 having the light-transmissive member 16 disposed in advance on its upper surface thereof, or the light-transmissive member 16 may be disposed on the upper surface of the light-emitting element 14 after the light-emitting element 14 is disposed on the substrate 13.

After bonding the light-emitting element 14 onto the substrate 13, the embedded member may be disposed between the substrate and the light-emitting element.

The manufacturing method of the light-emitting device according to the present embodiment may further include, as illustrated in FIG. 6C, disposing the covering member 15 configured to cover the lateral surface of the light-emitting element 14 placed on the substrate 13 and the lateral surface of the protrusion 12A.

The covering member 15 may be formed by utilizing a known method such as injection molding, potting, resin printing, transfer molding, compression molding or the like, for example. In this case, the covering member 15 may be formed so as to embed the light extraction surface of the light-emitting element or the light-transmissive member 16 and the top 12C of the protrusion 12A, and then the light extraction surface and the top 12C may be exposed by etching, polishing, or the like.

By using such methods, the protrusion can be easily formed at a desired position with an adequate width and height. This makes it possible to suppress, when one of the adjacent light-emitting elements is turned on and the other is turned off, the occurrence of pseudo-lighting in which light emitted from the turned-on light-emitting element is absorbed and/or reflected by the turned-off light-emitting element, and the turned-off light-emitting element appears to lightly emit light. In this manner, the light-emitting device having a prominent difference in brightness between a light-emitting portion and a non-light-emitting portion can be obtained.

The light-emitting device of the present invention can be used in various types of light sources, such as light sources for illumination, light sources for various indicators, on-vehicle light sources, display light sources, liquid crystal backlighting light sources, light sources for traffic signals, light sources for on-vehicle components, light sources for billboard channel letters and the like.

What is claimed is:

1. A light-emitting device comprising:
a substrate including a base body and a metal layer disposed on an upper surface of the base body; and
a plurality of light-emitting elements disposed on the metal layer, wherein
the metal layer includes, between adjacent ones of the light-emitting elements, a protrusion having a top located at a position higher than upper surfaces of the adjacent ones of the light-emitting elements.

2. The light-emitting device according to claim 1, further comprising
a covering member covering a lateral surface of the light-emitting element and a lateral surface of the protrusion.

3. The light-emitting device according to claim 1, further comprising
a light-transmissive member disposed on an upper surface of a corresponding one of the light-emitting elements.

4. The light-emitting device according to claim 3, further comprising
a covering member covering a lateral surface of the light-emitting element, a lateral surface of the protrusion, and a lateral surface of the light-transmissive member.

5. The light-emitting device according to claim 3, wherein
the top of the protrusion is located at a position higher than an upper surface of the light-transmissive member.

6. The light-emitting device according to claim 3, wherein
the light-transmissive member includes a first light-transmissive layer containing a phosphor and disposed on the upper surface of the corresponding one of the light-emitting elements, and a second light-transmissive layer disposed on the first light-transmissive layer, and
the top of the protrusion is located at a position higher than an upper surface of the first light-transmissive layer.

7. The light-emitting device according to claim 6, wherein
the second light-transmissive layer contains a glass material.

8. The light-emitting device according to claim 3, wherein
a height from a lower surface to the upper surface of the corresponding one of the light-emitting elements is lower than a height from a lower surface to an upper surface of the light-transmissive member.

9. The light-emitting device according to claim 1, wherein
the metal layer includes a plurality of protrusions including the protrusion, and
the protrusions are intermittently disposed around a corresponding one of the light-emitting elements in a plan view.

10. The light-emitting device according to claim 1, wherein
the protrusion has a width of 50 μm or less between the adjacent ones of the light-emitting elements.

11. The light-emitting device according to claim 1, wherein
the protrusion has a width that varies along a height direction of the protrusion.

12. The light-emitting device according to claim 3, wherein
an upper surface of the covering member is flush with an upper surface of the light-transmissive member.

13. The light-emitting device according to claim 2, wherein
the protrusion is exposed from the covering member on an upper surface of the light-emitting device.

14. The light emitting device according to claim 1, wherein
the metal layer includes a first portion on which at least one of the light emitting elements is disposed, and a second portion on which the protrusion is formed, the second portion being spaced apart from the first portion.

15. A manufacturing method of a light-emitting device, the method comprising:
preparing a substrate that includes a base body and a metal layer disposed on an upper surface of the base body, the metal layer including a plurality of protrusions; and
placing a light-emitting element on the metal layer between adjacent ones of the protrusions.

16. The manufacturing method of the light-emitting device according to claim 15, wherein
the preparing of the substrate includes
preparing the base body including a flat metal layer on the upper surface of the base body, and
forming the protrusions on the flat metal layer by electrolytic plating.
